(19) United States
(12) Patent Application Publication
(10) Pub. No.: US 2003/0005954 A1
(43) Pub. Date: Jan. 9, 2003

(54) Solar cell module and method of manufacturing the same

(76) Inventors: Makiko Emoto, Tokyo (JP); Akio Shibata, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/186,616

(22) Filed: Jul. 2, 2002

(30) Foreign Application Priority Data
Jul. 4, 2001 (JP) 2001-203196

(51) Int. Cl. H01L 31/00

(52) U.S. Cl. 136/244; 136/251; 136/258; 438/80; 438/97

(57) ABSTRACT

A semiconductor crystal substrate is fixed in a bent state to a support body. Preferably, the semiconductor crystal substrate is bonded to a transparent resin member provided between a surface cover member and a back cover member.

### BACKGROUND OF THE INVENTION

1. Field of the Invention

The present invention relates to a solar cell module and a method of manufacturing a solar cell module, and more particularly to a solar cell module having a thin-film semiconductor crystal substrate and a method of manufacturing such a solar cell module.

2. Description of the Related Art

A solar cell is a semiconductor electric-junction device which absorbs the radiant energy of sunlight and converts it directly into electric power. In order to absorb the radiant energy of sunlight efficiently, it is desirable that a solar cell module should be placed on a roof or the like having a curved surface. There has heretofore been demand for forming a solar cell module on a surface of a curved structure to convert solar radiation into electric power efficiently. A solar cell module that can be placed in such a place having a curved surface structure, i.e. a structure having a curved surface, can be manufactured by making an amorphous solar cell on a sheet having a curved surface structure. However, the amorphous solar cell has been disadvantageous in that conversion efficiency to convert solar radiation into electric power is too low to generate large electric power in a relatively small area.

On the other hand, a solar cell comprising a monocrystalline or polycrystalline silicon substrate can convert solar radiation into electric power highly efficiently. However, since the solar cell comprising silicon substrate is generally thick, it cannot easily be bent into a curved shape. Therefore, solar cell modules comprising flat plate-shaped solar cells have been put on the market. If solar cell modules can be formed into not only a flat shape but also a curved shape, then they can be placed in much more sites than if they are limited to a flat shape.

### SUMMARY OF THE INVENTION

It is therefore an object of the present invention to provide a solar cell module having a curved surface structure which can convert solar radiation into electric power at high conversion efficiency, and a method of manufacturing such a solar cell module.

According to the present invention, there is provided a solar cell module comprising a semiconductor crystal substrate and a support body having a curved surface structure, the semiconductor crystal substrate being fixed in a bent state to the support body.

According to the present invention, there is also provided a method of manufacturing a solar cell module, comprising disposing a semiconductor crystal substrate between uncured resin members, pressing the uncured resin members with the semiconductor crystal substrate against a surface cover member having a curved surface structure, and heating the uncured resin members for curing the resin members so as to hold the semiconductor crystal substrate in a bent state and be bonded to the surface cover member.

With the above arrangement, the semiconductor crystal substrate, which serves as a solar cell, has a very small thickness of 150 μm or less, for example, and hence can be bent and fixed to the support body having the curved surface structure. Thus, the solar cell module having a curved structure can be produced, and can convert solar radiation into electric power at high conversion efficiency by using the semiconductor crystal substrate.

The above and other objects, features, and advantages of the present invention will become apparent from the following description when taken in conjunction with the accompanying drawings which illustrate a preferred embodiment of the present invention by way of example.

### BRIEF DESCRIPTION OF THE DRAWINGS

FIG. 1 is a cross-sectional view of a solar cell module according to an embodiment of the present invention;

FIGS. 2A and 2B are views illustrating a process of forming a surface cover member;

FIG. 3 is a schematic view illustrating a method of manufacturing the solar cell module according to the embodiment of the present invention; and

FIG. 4 is a schematic view illustrating a method of manufacturing the solar cell module according to another embodiment of the present invention.

### DETAILED DESCRIPTION OF THE PREFERRED EMBODIMENTS

Next, a solar cell module according to an embodiment of the present invention will be described with reference to FIGS. 1 through 4.

As shown in FIG. 1, a solar cell module 10 according to an embodiment of the present invention comprises a surface cover member 11 having a curved surface structure (structure having a curved surface), a back cover member 12, and a plurality of solar cells 13 sandwiched between the surface cover member 11 and the back cover member 12. Each of the solar cells 13 comprises a monocrystalline or polycrystalline silicon substrate having a thickness of 150 μm or less. The solar cells 13 are originally flat in shape. As shown in FIG. 1, since the solar cells 13 are thin, they are bent into a curved shape and fixedly held in their bent state in a transparent resin member 16. The solar cells 13 are electrically interconnected by wires 14. In this embodiment, the surface cover member 11, the back cover member 12, and the transparent resin member 16 compose a support body. The monocrystalline silicon substrate having a thickness of 150 μm or less may be available in the form of a ribbon-shaped crystal or web crystal manufactured by an apparatus disclosed in Japanese patent application No. 11-125064 (Japanese laid-open patent publication No. 2000-319088) or Japanese patent application No. 2000-275315.

The surface cover member 11 is made of transparent glass or plastic. For example, the surface cover member 11 preferably comprises a bent glass sheet having a thickness of about 3.2 mm for use in solar cell modules. The back cover member 12 preferably comprises a fluorine-based film, a metal sheet of aluminum or the like, a resin sheet, or a glass sheet. The back cover member 12 has a radius of curvature commensurate with the surface cover member 11. The radius of curvature of the surface cover member 11 may be reduced to a minimum of about 50 mm depending on the flexibility of the solar cells 13. The transparent resin member 16 may comprise an adhesive film of ethylene vinyl acetate (EVA) or the like. The transparent resin member 16 is in a crosslinked (cured) state and holds the solar cells 13 which are bent, and is joined to the surface cover member 11 and the back cover member 12. The transparent resin member 16 is transparent to visible radiation, and is capable of transmitting the incident solar radiation through the surface cover member 11 to the light receiving surfaces of the solar cells 13 without causing any substantial loss.

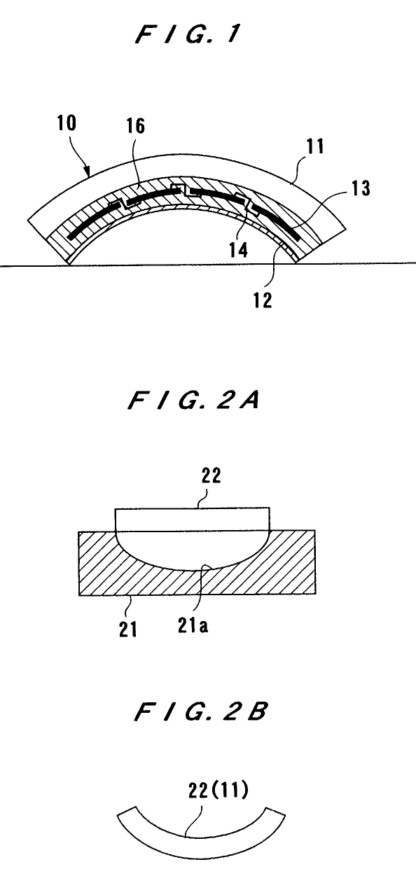

A method of manufacturing the solar cell module 10 will be described below. FIG. 2A illustrates a process of forming a surface cover member having a curved surface structure. First, a die 21 made of a metal such as SUS304 and having a concave surface 21a is prepared. Alternatively, the die 21 may be made of any materials insofar as such materials can withstand a temperature of about 1000° C. A glass sheet 22 made of soda glass, synthetic quartz glass, or the like, which is suitable for use in a flat solar cell module is prepared. Then, the glass sheet 22 is placed on the die 21 having the concave surface 21a. In this state, the die 21 and the glass sheet 22 are heated in a furnace to a temperature ranging from about 750 to 850° C. Thus, the glass sheet 22 is bent by its own weight and formed into a shape corresponding to the concave surface 21a of the die 21. Then, the temperature of the glass sheet 22 is slowly lowered so that the glass sheet 22 will not crack, thus producing a surface cover member 11 having a curved surface structure. In this manner, as shown in FIG. 2B, the glass sheet 22 becomes the curved surface structure, and is then used as the surface cover member 11. In this embodiment, the glass sheet 22 corresponds to a flat member.

In the illustrated embodiment, the flat glass sheet 22 is bent by its own weight and formed into the surface cover member 11 having the curved surface structure by using the die 21 having the concave surface 21a. Alternatively, the flat glass sheet 22 may forcibly be bent using a suitable tool such as two dies in such a manner that the flat glass sheet 22 is heated and deformed in a sandwiched state by the dies or the like. Alternatively, a softened glass sheet may be formed into a curved surface structure by a roll or the like, instead of the die 21. A commercially available curved glass sheet may be used as the surface cover member 11. The surface cover member 11 may alternatively be made of a plastic material such as polycarbonate. If the surface cover member is to be made of the plastic material, then the surface cover member having a curved shape may be produced by injection molding process or the like.

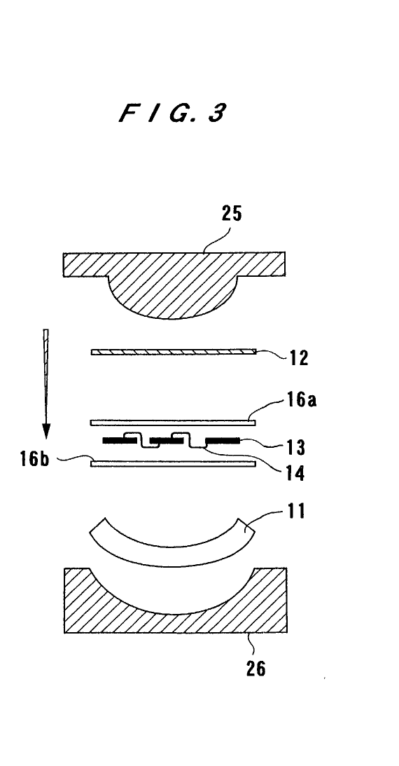

FIG. 3 illustrates a method of manufacturing the solar cell module 10 shown in FIG. 1. As shown in FIG. 3, the surface cover member 11 produced by the process shown in FIGS. 2A and 2B or another process, ethylene vinyl acetate (EVA) films 16a and 16b which are not cured, the solar cells 13, and the back cover member 12 are prepared. Each of the solar cells 13 comprises a monocrystalline or polycrystalline silicon substrate having a length of 10 cm, a width of 5 cm and a thickness of 150 μm or less. The solar cells 13 are electrically interconnected by wires 14. The EVA films 16a and 16b are disposed such that the solar cells 13 are placed between the EVA films 16a and 16b. The surface cover member 11 and the back cover member 12 are positioned below and above the laminated structure comprising the EVA films 16a and 16b and the solar cells 13. The back cover member 12 may comprise a fluorine-based film, for example, and this back cover member 12 should be selected in view of excellent environmental resistance properties including water resistance and humidity resistance.

Then, the laminated structure, which is composed of the surface cover member 11, the back cover member 12, the EVA films 16a and 16b, and the solar cells 13, is sandwiched between a convex pressing die 25 and a concave pressing die 26. The convex pressing die 25 is pressed against the concave pressing die 26 in a vacuum furnace at a temperature of about 200° C. for thereby heating and bonding the laminated structure. It is preferable to perform the heating and bonding of the laminated structure in a vacuum of 133 Pa or less at a constant temperature of about 200° C. for about 30 minutes.

Since the vacuum is produced for the purpose of evacuating air from a small space or a clearance between the EVA films 16a and 16b, the vacuum furnace may not necessarily be employed, but a local evacuating process may be used to evacuate air from the space between the EVA films 16a and 16b. In the compressing process, the laminated structure may be compressed under pneumatic or hydraulic pressure without using the pressing dies 25 and 26.

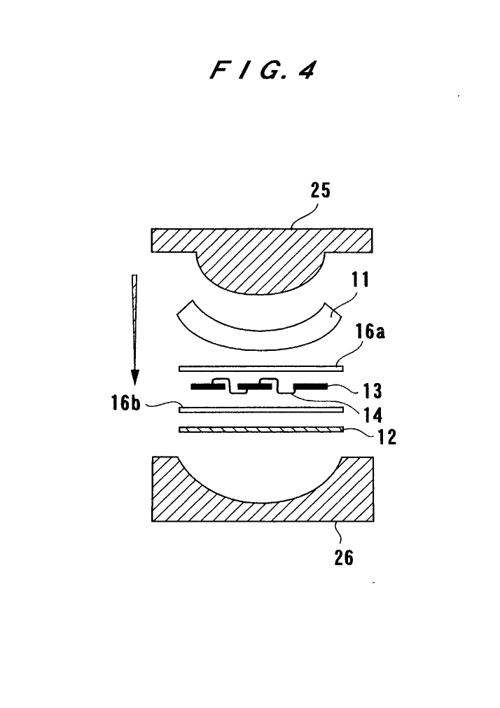

Alternatively, as shown in FIG. 4, the surface cover member 11 may be disposed at the convex pressing die 25 side and the back cover member 12 may be disposed at the concave pressing die 26 side. With this arrangement, the EVA films 16a and 16b with the solar cells 13 are bonded to the convex surface of the surface cover member 11. Therefore, the produced solar cell module can be placed on a roof or the like having a concave curved surface.

Because the laminated structure is heated and bonded in a vacuum furnace, air is evacuated from the space between the EVA films 16a and 16b, and the EVA films 16a and 16b are crosslinked and hence cured. Therefore, the EVA films 16a and 16b hold the solar cells 13 in their bent state and are firmly bonded to the surface cover member 11 and the back cover member 12. When thus being heated under pressure, the EVA films 16a and 16b are turned into the transparent resin member 16, thus producing a rigid laminated solar cell module structure. Excessive portions of the produced solar cell module structure are cut off, and wiring electrodes are formed, thereby completing the solar cell module 10 which is semicylindrical in shape. While the radius of curvature of the solar cell module 10 depends on the size of each of the solar cells 13, the material of the wires, and other conditions, the solar cell module 10 may have a minimum radius of curvature which is of about 50 mm.

In the illustrated embodiment, the curved surface structure of the solar cell module is produced using the die 21 having the concave surface 21a. Alternatively, a mold for forming a roof tile may be used to produce the curved structure of the solar cell module so that the solar cell module can fit the uppermost surface of the roof tile. Therefore, the solar cell module can be placed on the uppermost surface of the roof tile, and can efficiently convert solar radiation into electric power. The roofs of various buildings often have a curved surface structure for aesthetic reasons, and the solar cell module according to the present invention can preferably be used as one of building materials for such curved roofs. It is also possible to place the solar cell module according to the present invention on utility poles including an electric pole.

The solar cell module according to the present invention has the curved structure and achieves a high conversion efficiency to convert solar radiation into electric power. As the solar cell module according to the present invention has the curved structure, it can be installed in much more sites than conventional flat solar cell modules.

Although a certain preferred embodiment of the present invention has been shown and described in detail, it should be understood that various changes and modifications may be made therein without departing from the scope of the appended claims.

The present invention is applicable to a solar cell module and a method of manufacturing a solar cell module, and more particularly to a solar cell module having a thin-film semiconductor crystal substrate and a method of manufacturing such a solar cell module.

What is claimed is:

1. A solar cell module comprising:
a semiconductor crystal substrate; and
a support body having a curved surface structure, said semiconductor crystal substrate being fixed in a bent state to said support body.

2. A solar cell module according to claim 1, wherein said semiconductor crystal substrate is sandwiched between a surface cover member having a curved surface structure and a back cover member.

3. A solar cell module according to claim 2, wherein said semiconductor crystal substrate is fixedly held in said bent state in a transparent resin member.

4. A solar cell module according to claim 1, wherein said semiconductor crystal substrate comprises a monocrystalline or polycrystalline silicon substrate.

5. A solar cell module according to claim 1, wherein said semiconductor crystal substrate has a thickness of 150 μm or less.

6. A solar cell module according to claim 3, wherein said transparent resin member comprises an ethylene vinyl acetate film.

7. A solar cell module according to claim 1, wherein a plurality of semiconductor crystal substrates are fixed to said support body, and said semiconductor crystal substrates are electrically interconnected by wires.

8. A solar cell module according to claim 1, wherein said solar cell module is semicylindrical in shape.
disposing a semiconductor crystal substrate between uncured resin members;
pressing said uncured resin members with said semiconductor crystal substrate against a surface cover member having a curved surface structure; and
heating said uncured resin members for curing said resin members so as to hold said semiconductor crystal substrate in a bent state and be bonded to said surface cover member.

10. A method according to claim 9, further comprising:
preparing a flat member; and
heating said flat member for bending said flat member so as to form said curved surface structure.

11. A method according to claim 9, further comprising:
preparing a flat member; and
heating said flat member while pressing said flat member for bending said flat member so as to form said curved surface structure.

12. A method according to claim 9, wherein said resin members are heated and cured in a vacuum furnace.

13. A method according to claim 9, wherein said semiconductor crystal substrate comprises a monocrystalline or polycrystalline silicon substrate.

14. A method according to claim 9, wherein said semiconductor crystal substrate has a thickness of 150 μm or less.

15. A method according to claim 9, wherein a plurality of semiconductor crystal substrates are disposed between said resin members.

16. A method according to claim 9, wherein a mold for forming a roof tile is used for forming said curved surface structure.
